(19) United States
(12) Patent Application Publication
(10) Pub. No.: US 2026/0156831 A1
(43) Pub. Date: Jun. 4, 2026

(54) MRAM WITH RECESSED REFERENCE LAYER MESA

(71) Applicant: International Business Machines Corporation, Armonk, NY (US)

(72) Inventors: Oscar van der Straten, Guilderland Center, NY (US); Willie Lester Muchrison, JR., Troy, NY (US); Chih-Chao Yang, Glenmont, NY (US)

(21) Appl. No.: 18/967,209

(22) Filed: Dec. 3, 2024

(51) Int. Cl. H10B 61/00; G01R 33/09; H10N 50/10; H10N 50/80

(52) U.S. Cl. CPC H10B 61/10; G01R 33/098; H10N 50/10; H10N 50/80

(57) ABSTRACT

A semiconductor device is provided. The semiconductor device includes a memory including a bottom electrode, a magnetic tunnel junction (MTJ) stack on the bottom electrode, and an upper electrode on the MTJ stack. The semiconductor device also includes at least one dielectric layer formed around the memory, wherein a top metal layer contact hole is formed in the at least one dielectric layer, a dielectric liner layer formed in the top metal contact hole, and a top metal layer contact in the top metal layer contact hole.

### BACKGROUND

The present disclosure relates to magnetic random-access memory (MRAM) devices based on magnetic tunnel junction (MTJ) structures. Certain MRAM devices may be fabricated to include a bottom electrode, an MRAM stack, and a top electrode. In general, MRAM devices may be used in a variety of applications. One example application is embedded storage (e.g., eFlash replacement). Another example is cache (e.g., embedded dynamic random-access memory (eDRAM), or static random-access memory (SRAM)). Preventing electrical shorting among various layers of the memory device may be desirable.

### SUMMARY

Embodiments of the present disclosure relate to a semiconductor device. The semiconductor device includes a magnetic tunnel junction (MTJ) stack including a reference layer including an inner portion and an outer portion surrounding the inner portion, where the inner portion has a greater thickness than the outer portion, a tunnel barrier layer, and a magnetic free layer.

Other embodiments relate to a semiconductor device. The semiconductor device includes a magnetic tunnel junction (MTJ) stack including a reference layer having a mesa structure that includes a lower portion having a first width and an upper portion having a second width, where the first width is greater than the second width, a tunnel barrier layer, and a magnetic free layer.

Other embodiments of the present disclosure relate to an electronic device. The electronic device includes a semiconductor device. The semiconductor device includes a magnetic tunnel junction (MTJ) stack including a reference layer including an inner portion and an outer portion surrounding the inner portion, where the inner portion has a greater thickness than the outer portion, a tunnel barrier layer, and a magnetic free layer.

The above summary is not intended to describe each illustrated embodiment or every implementation of the present disclosure.

### BRIEF DESCRIPTION OF THE DRAWINGS

The drawings included in the present application are incorporated into, and form part of the specification. They illustrate embodiments of the present disclosure and, along with the description, explain the principles of the disclosure. The drawings are only illustrative of certain embodiments and do not limit the disclosure.

FIG. 1 is a cross-sectional view of a semiconductor device that includes an MRAM device at an intermediate stage of the manufacturing process, according to embodiments.

FIG. 2 is a cross-sectional view of the semiconductor device of FIG. 1 after additional fabrication operations, according to embodiments.

FIG. 3 is a cross-sectional view of the semiconductor device of FIG. 2 after additional fabrication operations, according to embodiments.

FIG. 4 is a cross-sectional view of the semiconductor device of FIG. 3 after additional fabrication operations, according to embodiments.

FIG. 5 is a cross-sectional view of the semiconductor device of FIG. 4 after additional fabrication operations, according to embodiments.

FIG. 6 is a cross-sectional view of the semiconductor device of FIG. 5 after additional fabrication operations, according to embodiments.

FIG. 7 is a cross-sectional view of the semiconductor device of FIG. 6 after additional fabrication operations, according to embodiments.

FIG. 8 is a cross-sectional view of the semiconductor device of FIG. 7 after additional fabrication operations, according to embodiments.

FIG. 9 is a cross-sectional view of the semiconductor device of FIG. 8 after additional fabrication operations, according to embodiments.

FIG. 10 is a cross-sectional view of the semiconductor device of FIG. 9 after additional fabrication operations, according to embodiments.

FIG. 11 is a cross-sectional view of the semiconductor device of FIG. 10 after additional fabrication operations, according to embodiments.

FIG. 12 is a cross-sectional view of the semiconductor device of FIG. 11 after additional fabrication operations, according to embodiments.

FIG. 13 is a cross-sectional view of the semiconductor device of FIG. 12 after additional fabrication operations, according to embodiments.

FIG. 14 is a cross-sectional view of the semiconductor device of FIG. 13 after additional fabrication operations, according to embodiments.

FIG. 15 is a cross-sectional view of the semiconductor device of FIG. 14 after additional fabrication operations, according to embodiments.

FIG. 16 is a cross-sectional view of the semiconductor device of FIG. 15 after additional fabrication operations, according to embodiments.

FIG. 17 is a cross-sectional view of the semiconductor device of FIG. 16 after additional fabrication operations, according to embodiments.

FIG. 18 is a cross-sectional view of the semiconductor device of FIG. 17 after additional fabrication operations, according to embodiments.

FIG. 19 is a cross-sectional view of the semiconductor device of FIG. 18 after additional fabrication operations, according to embodiments.

FIG. 20 is a cross-sectional view of the semiconductor device of FIG. 19 after additional fabrication operations, according to embodiments.

FIG. 21 is a cross-sectional view of the semiconductor device of FIG. 20 after additional fabrication operations, according to embodiments.

FIG. 22 is a cross-sectional view of the semiconductor device of FIG. 21 after additional fabrication operations, according to embodiments.

FIG. 23 is a cross-sectional view of the semiconductor device of FIG. 22 after additional fabrication operations, according to embodiments.

FIG. 24 is a cross-sectional view of the semiconductor device of FIG. 23 after additional fabrication operations, according to embodiments.

### DETAILED DESCRIPTION

The present disclosure describes MRAM devices including magnetic tunnel junction (“MTJ”) stacks and methods of manufacturing MRAM devices. In particular, the present disclosure describes MRAM devices and methods of manufacturing same, the MRAM devices including a recessed reference layer having a mesa structure. The present embodiments may also improve the performance of embedded MRAM devices due to reduced electrical shorts caused by metal re-sputtering on the sidewalls of the MTJ stacks.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of elements can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto a surface, such as the surface of a wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film’s electrical and mechanical properties.

Removal/etching is any process that removes material from a surface, such as the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties of a material by doping, for example, transistor sources and drains, generally by diffusion and/or by ion implantation. These doping processes may be followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) may be used to connect and isolate transistors and their components. Selective doping of various regions of the semiconductor substrate allows the conductivity of the substrate to be changed with the application of voltage. By creating structures of these various components, billions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed using a light sensitive polymer called a photo-resist. To build the complex structures that make up a transistor and the many wires that connect the millions of transistors of a circuit, lithography and etch pattern transfer operations are repeated multiple times. Each pattern being formed on the wafer is aligned to the previously formed patterns and slowly the conductors, insulators and selectively doped regions are built up to form the final device.

Turning now to an overview of technologies that are more specifically relevant to aspects of the present disclosure, embedded DRAM (eDRAM) is a dynamic random-access memory (DRAM) integrated on the same die or multi-chip module (MCM) of an application-specific integrated circuit (ASIC) or microprocessor. eDRAM has been implemented in silicon-on-insulator (SOI) technology, which refers to the use of a layered silicon–insulator–silicon substrate in place of conventional silicon substrates in semiconductor manufacturing. eDRAM technology has met with varying degrees of success, and demand for SOI technology as a server memory option has decreased in recent years. Magnetoresistive random-access memory (MRAM) devices using magnetic tunnel junctions (MTJ) are one option to replace existing eDRAM technologies. MRAM is a non-volatile memory, and this benefit is a driving factor that is accelerating the development of this memory technology.

A magnetic tunnel junction (MTJ) device, which is a primary storage element in a magnetic random-access memory (MRAM), is a magnetic storage and switching device in which two ferromagnetic layers are separated by a thin insulating oxide layer (i.e., a tunnel barrier layer) to form a stacked structure. The tunnel barrier layer may comprise, for example, magnesium oxide or aluminum oxide. One of the ferromagnetic layers has a magnetization that is fixed, and it is therefore referred to as a magnetic fixed layer (or pinned layer, or reference layer). However, the other ferromagnetic layer has a magnetization that can change, and it is therefore referred to as a free layer (or magnetic free layer). When a bias voltage is applied to the MTJ device, electrons that are spin polarized by the ferromagnetic layers traverse the insulating barrier through a process known as quantum tunneling to generate an electric current whose magnitude depends on an orientation of magnetization of the ferromagnetic layers. The MTJ device will exhibit a low resistance when a magnetic moment of the free layer is parallel to the fixed layer magnetic moment, and it will exhibit a high resistance when the magnetic moment of the free layer is oriented anti-parallel to the fixed layer magnetic moment.

The materials and geometries used to build the stack of different layers forming the MTJ device are factors that affect the characteristics of the device in terms of speed (i.e., switching time) and power consumption (e.g., voltage and/or current required to switch the device from one state to another). As discussed above, certain MTJ devices have a pillar structure (i.e., a stack of materials) having a cylindrical shape, where current flows from a top layer to a bottom layer, or vice versa, in order to switch the magnetization of one ferromagnetic layer. These types of MTJ devices are generally referred to as spin transfer torque (STT) MTJ devices. Certain STT MRAM devices may have limited switching speed and endurance in comparison to static random-access memory (SRAM) devices (i.e., random access memory that retains data bits in its memory as long as power is being supplied). Other types of MTJ devices are referred to as spin orbit torque (SOT) devices. In the SOT type of device, the stacked pillar structure is still cylindrically shaped, but the stack is deposited on top of a heavy metal conductor. In the SOT type of MTJ device, current flows horizontally in this conductor and switches the magnetization of the ferromagnetic layer at the interface.

In STT type MRAM devices, the manufacture of the devices is often performed in conjunction with forming middle-of-line (MOL) or back-end-of-line (BEOL) layers. This may be referred to as embedded MRAM, where the MRAM devices are embedded in, or formed in conjunction with these layers. In general, front-end-of-line (FEOL) refers to the set of process steps that form transistors and other circuit elements (such as resistors and capacitors) that are later connected electrically with middle-of-line (MOL) and back-end-of-line (BEOL) layers. In general, MOL refers to the set of wafer processing steps used to create the structures that provide the local electrical connections between transistors (e.g., gate contact formation). MOL processing generally occurs after FEOL processes and before BEOL processes. In general, the BEOL is the portion of IC fabrication where the individual devices (transistors, capacitors, resistors, etc.) are interconnected with wiring on the wafer.

As discussed above, MRAM devices may be useful for a variety of different applications, such as embedded storage and cache. For high performance MRAM devices based on perpendicular magnetic tunnel junction (MTJ) structures, well-defined interfaces and interface control may be important. Certain MTJ structures may include, for example, a Co-based synthetic anti-ferromagnet (SAF), a CoFeB-based reference layer, a MgO-based tunnel barrier, a CoFeB-based free layer, and cap layers containing e.g., Ta and/or Ru. Embedded MTJ structures are usually formed by patterning of blanket MTJ stacks.

During the formation of the MTJ stacks, reactive ion etching (RIE), and ion beam etching (IBE) processing of the stacks may present certain challenges, as these processing steps can lead to electrical shorts due to re-sputtering of the thick bottom metal layers onto the MTJ stack sidewalls. Also, after MTJ stack patterning, the inter-pillar spaces may be filled with interlayer dielectric (ILD) material to enable a connection to a BEOL wiring by a top contact level. ILD gap filling between pillars may present a challenge because the presence of any voids in the ILD between the pillars can lead to electrical shorts. However, as described in detail herein, the present embodiments provide a method and structure for forming a reference layer with a recessed mesa structure that is filled with a dielectric material. Due to the recessed reference layer with the mesa structure, this may reduce or prevent metal re-sputtering on various layers, which may allow for a reduced risk of electrical shorting due to metal re-sputtering. Moreover, the present embodiments provide embedded MTJ structures that have a reduced risk of ILD void induced shorts.

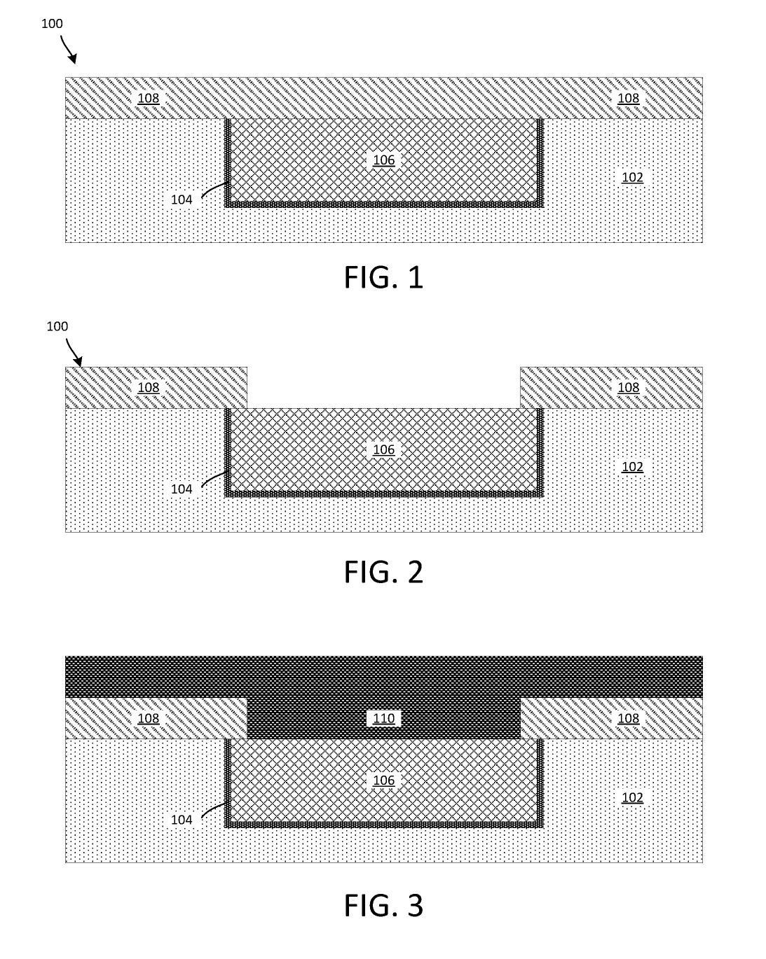

Referring now to the drawings in which like numerals represent the same or similar elements and initially to FIG. 1, an exemplary method of manufacturing a semiconductor device 100 (i.e., an MRAM device) to which the present embodiments may be applied is shown. In certain examples, several back end of line (“BEOL”) layers (not shown) and front end of line (FEOL) layers (not shown) may be formed. The BEOL metal layers can include, for example, Cu, TaN, Ta, Ti, TiN or a combination thereof. A BEOL dielectric layer (not shown) may be formed on the sides of one or more of the BEOL metal layers. The BEOL dielectric layer may be composed of, for example, SiOₓ, SiNₓ, SiBCN, low-κ, or any other suitable dielectric material. The structure including the FEOL/BEOL layers may be a starting structure upon which the MRAM devices are formed.

As shown in the semiconductor device 100 of FIG. 1, a first ILD layer 102 is formed. Then, a suitable combination of patterning and material removal processes are performed to form bottom metal contact holes (not shown). Then, as shown in FIG. 1, a bottom barrier layer 104 is first formed in the bottom metal contact holes. The bottom barrier layer 104 may comprise, for example, Ta or TaN. Then, a bottom metal contact 106 (or bottom metal layer) is deposited on the bottom barrier layer 104 and fills in the remainder of the bottom metal contact hole. This bottom metal contact 106 may be included in one of the BEOL layers. In certain examples, the bottom metal contact 106 (e.g., an M1 level interconnect wire) may include, Cu, Co, Nb, NbN, W, WN, Ta, TaN, Ti, TiN, Ru, Mo, Cr, V, Pd, Pt, Rh, Sc, Al and other metals or conductive metal nitrides. It should be appreciated that the interconnect structure shown in FIG. 1 is merely one example, and any other suitable interconnect structure (e.g., number of layers, size, number of contacts, etc.) may be used. Then, in certain examples, an optional material removal process such as chemical mechanical planarization (CMP) may be performed to planarize the surface of the semiconductor device 100. As shown in FIG. 1, a dielectric cap 108 is formed on the top surfaces of the first ILD layer 102, the bottom barrier layer 104 and the bottom metal contact 106. Certain examples of materials that may be used for the dielectric cap 108 may include SiN and SiCN.

Referring now to FIG. 2, this figure is a cross-sectional view of the semiconductor device 100 of FIG. 1 after additional fabrication operations, according to embodiments. As shown in FIG. 2, suitable patterning and material removal processes are performed on the dielectric cap 108 to expose the top surface of the bottom metal contact 106 (or wiring) without exposing the bottom barrier layer 104 or the first ILD layer 102.

Referring now to FIG. 3, this figure is a cross-sectional view of the semiconductor device 100 of FIG. 2 after additional fabrication operations, according to embodiments. As shown in FIG. 3, a suitable material deposition process is performed to form a metal cap layer 110. The metal cap layer 110 fills in the spaces between the different portions of the dielectric cap 108. In certain examples, the metal cap layer 110 may comprise TaN or tungsten (W). As shown in FIG. 3, the metal cap layer 110 may initially be formed in excess so that a portion of the metal cap layer 110 extends above the top surface of the dielectric cap 108.

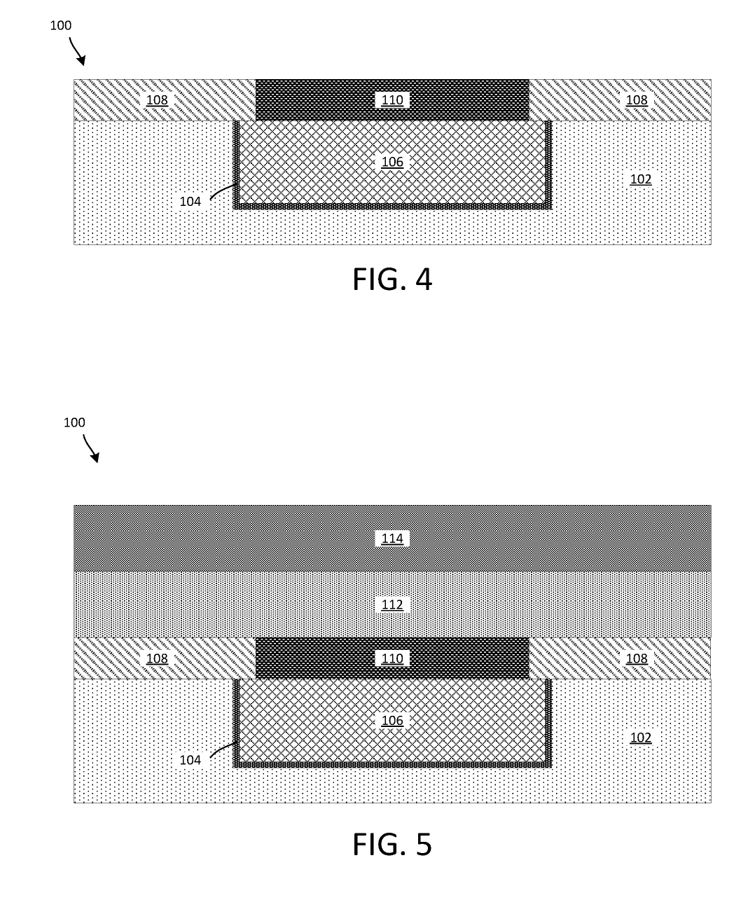

Referring now to FIG. 4, this figure is a cross-sectional view of the semiconductor device 100 of FIG. 3 after additional fabrication operations, according to embodiments. As shown in FIG. 4, a suitable material removal process (e.g., CMP) may be performed to remove any excess material of the metal cap layer 110 and to planarize the upper surface of the semiconductor device 100. After this processing step, the upper surfaces of the dielectric cap 108 are exposed.

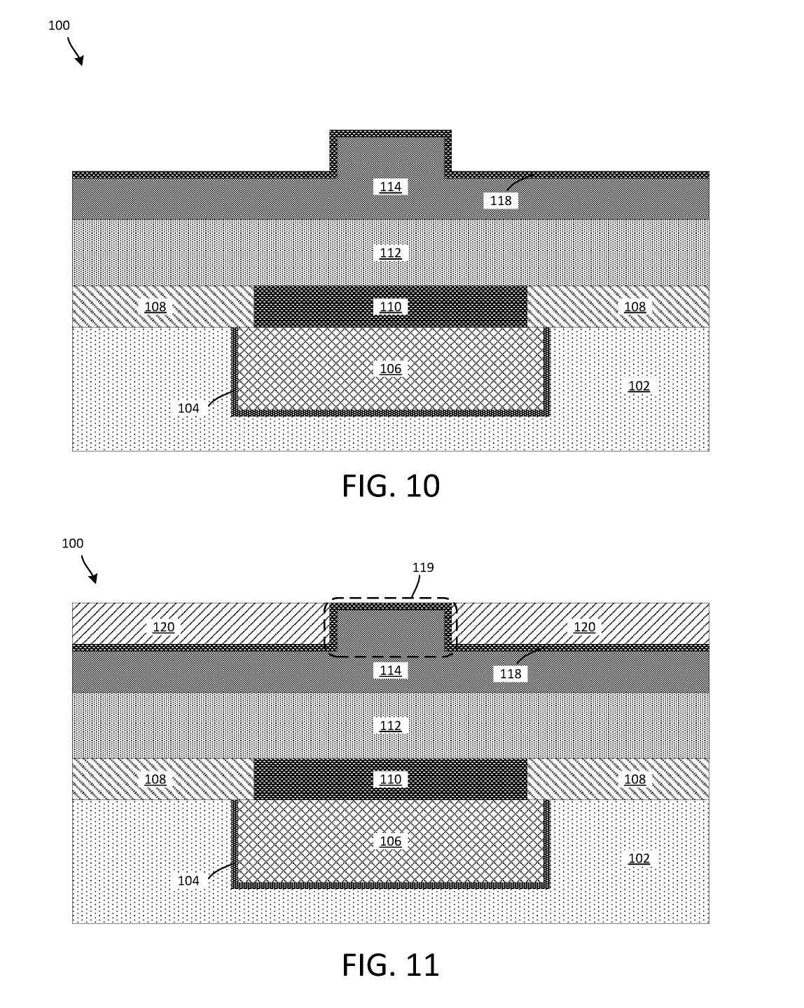

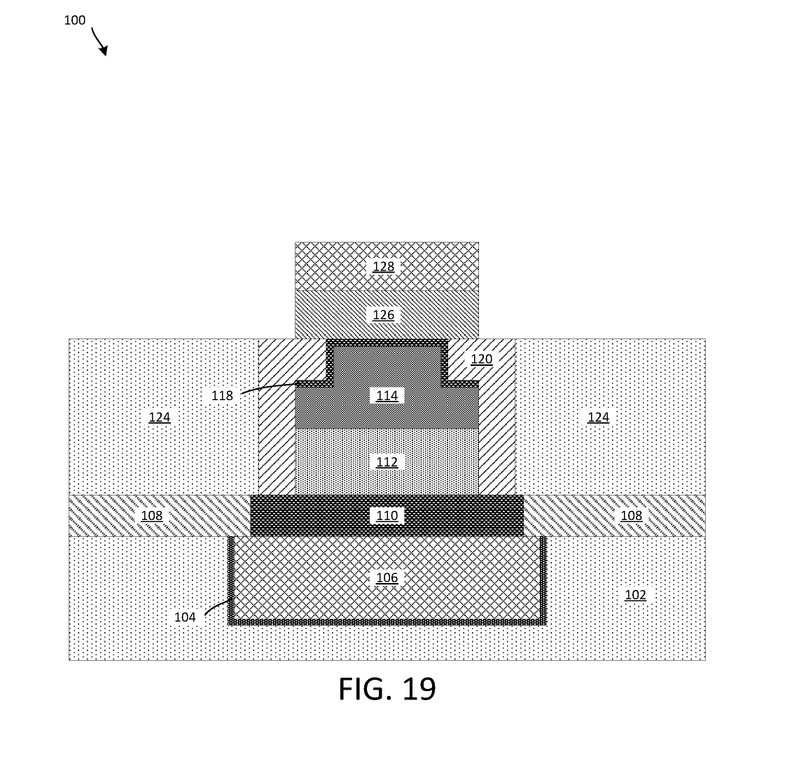

Referring now to FIG. 5, this figure is a cross-sectional view of the semiconductor device 100 of FIG. 4 after additional fabrication operations, according to embodiments. As shown in FIG. 5, a material deposition step is performed to form the bottom electrode 112. In certain examples, the bottom electrode 112 may comprise Nb, NbN, W, WN, Ta, TaN, Ti, Ru, Mo, Cr, V, Pd, Pt, Rh, Sc, ScN, Al and other high melting point metals or conductive metal nitrides, or any other suitable conductive material(s) for use in an electrode. As also shown in FIG. 5, after the formation of the bottom electrode 112, a reference layer 114 (i.e., one of the active layers of the MRAM device) is formed on top of the bottom electrode 112. In general, the MTJ stack may include multiple layers such as, for example, multiple magnetic layers separated by an insulating layer. In certain embodiments, the MTJ stack includes the reference layer 114, a tunnel barrier layer 118 (see FIG. 10), and a magnetic free layer 126 (see FIG. 19). The reference layer 114 (or fixed layer) may, for example, be annealed in a magnetic field to set a polarization state of the reference layer 114 in the MTJ stack.

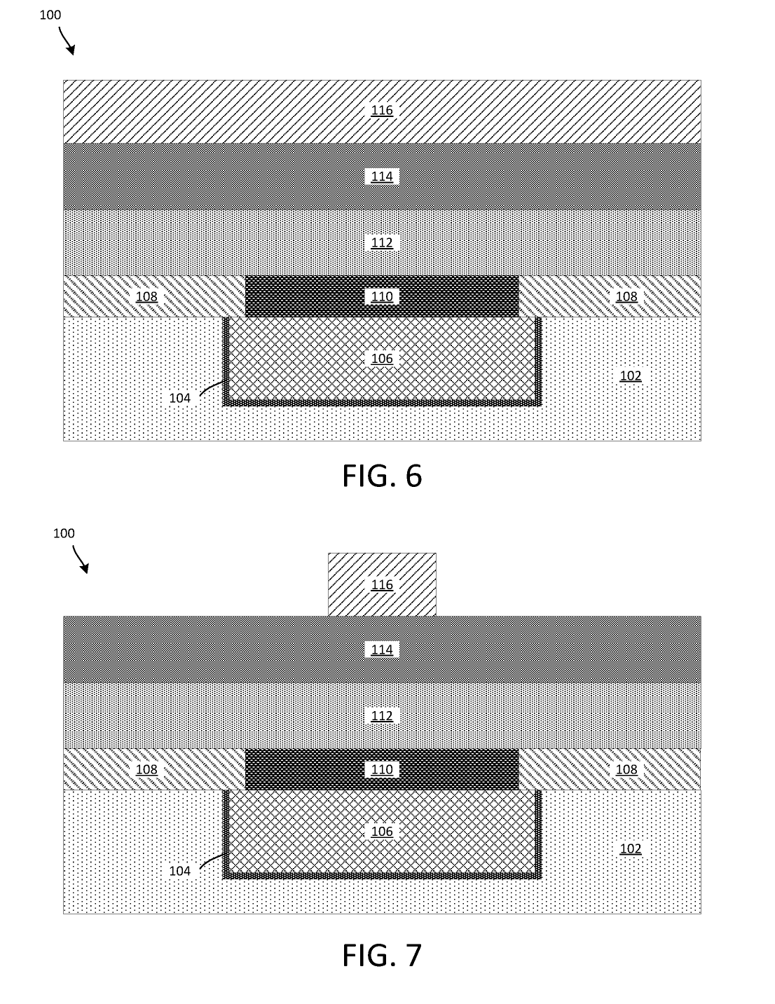

Referring now to FIGS. 6 and 7, these figures are cross-sectional views of the semiconductor device 100 of FIG. 5 after additional fabrication operations, according to embodiments. As shown in FIG. 6, a hardmask layer 116 is deposited on top of the reference layer 114. Then, as shown in FIG. 7, the hardmask layer 116 is patterned to a dimension that will allow for subsequent formation of the mesa structure of the reference layer 114, as discussed in further detail below. In certain examples, the material of the hardmask layer 116 may be TaN or any other suitable material(s). For example, the hardmask layer 116 may include one or more of the following materials: TaN, WCN; TiN; TaAlN; WN; TEOS; low-κ and ULK etc.

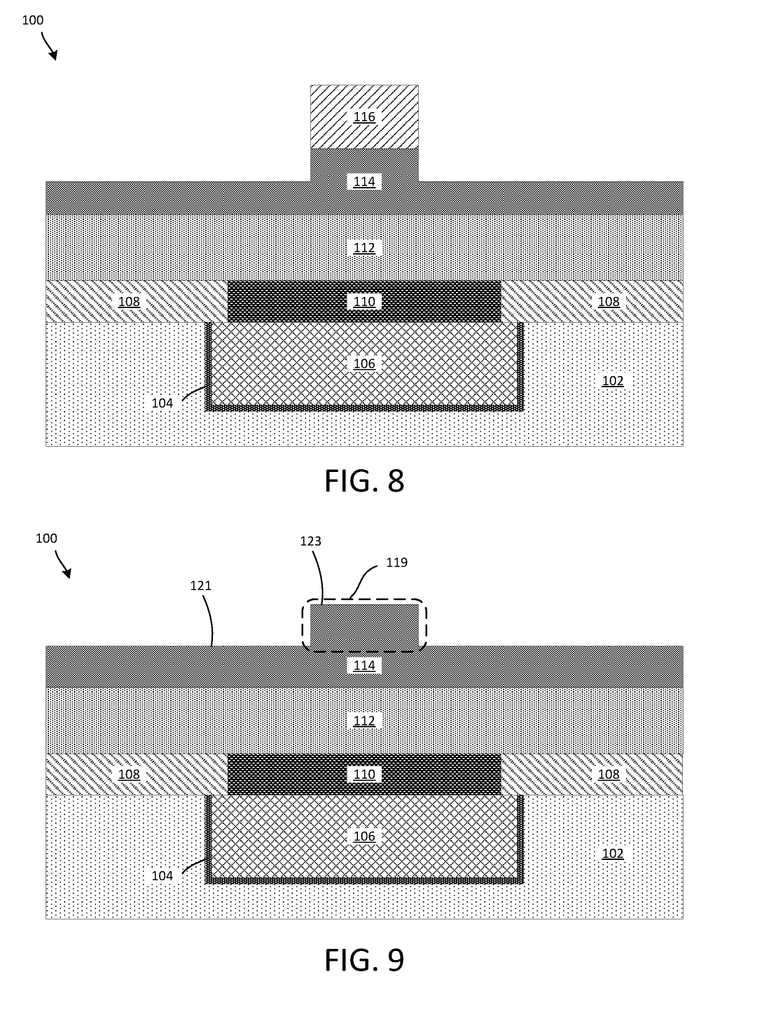

Referring now to FIGS. 8 and 9, these figures are cross-sectional views of the semiconductor device 100 of FIG. 7 after additional fabrication operations, according to embodiments. As shown in FIG. 8, a suitable material removal process is performed (e.g., etching) to remove a certain thickness of the reference layer 114 using the hardmask layer 116 to pattern the reference layer 114 and form a mesa structure 119 of the reference layer 114, as indicated by the dashed line area in FIG. 9. As used herein, a mesa structure 119 (or mesa shape, or mesa portion) may be considered to be a portion of the reference layer 114 formed at a higher level than a first top surface 121 of the reference layer 114. That is, a second top surface 123 of the mesa structure 119 is higher than the first top surface 121 of the reference layer 114. In certain examples, the first top surface 121 and the second top surface 123 are both horizontal and parallel with respect to each other. In certain examples, a width of the mesa structure 119 of the reference layer 114 may be less than a width of the bottom metal contact 106 and/or the metal cap layer 110. Thus, in certain embodiments, the reference layer includes an inner portion and an outer portion surrounding the inner portion, where the inner portion has a greater thickness than the outer portion. In certain examples, the inner portion and the outer portion of the reference layer 114 both have a cylindrical shape. Also in certain embodiments, the reference layer includes a mesa structure that includes a lower portion having a first width and an upper portion having a second width, where the first width is greater than the second width. In certain embodiments a tunnel barrier layer 118 (see, FIG. 10) is formed on both the lower portion and the upper portion of the reference layer 114. In certain examples, the upper portion and the lower portion of the reference layer 114 both have a cylindrical shape. As shown in FIG. 9, a suitable material removal process is used to remove the hardmask layer 116.

Referring now to FIG. 10, this figure is a cross-sectional view of the semiconductor device 100 of FIG. 9 after additional fabrication operations, according to embodiments. As shown in FIG. 10, a suitable material deposition process is utilized to form a tunnel barrier layer 118 on the reference layer 114, including the top and sidewalls of the mesa portion 119. Thus, in certain embodiments, tunnel barrier layer 118 is formed on both the inner portion and the outer portion of the reference layer 114, and the tunnel barrier layer is also formed on vertical sidewalls of the inner portion of the reference layer 114. In certain embodiments, the tunnel barrier layer 118 is a barrier, such as a thin insulating layer or electric potential, between two electrically conducting materials. Electrons (or quasiparticles) pass through the tunnel barrier layer 118 by the process of quantum tunneling. In certain embodiments, the tunnel barrier layer 118 includes at least one sublayer composed of MgO.

Referring now to FIG. 11, this figure is a cross-sectional view of the semiconductor device 100 of FIG. 10 after additional fabrication operations, according to embodiments. As shown in FIG. 11, a suitable material deposition process is utilized to form a encapsulation layer 120. In certain examples, the encapsulation layer 120 comprises SiN or any other suitable dielectric material(s). In certain examples, the encapsulation layer 120 may initially be formed to a height that is above the top surface of the tunnel barrier layer 118. In these examples, a suitable material removal process (e.g., CMP) may be used to planarize and remove any excess material of the encapsulation layer 120, thereby exposing the tunnel barrier layer 118 at a location of the mesa structure 119 of the reference layer 114.

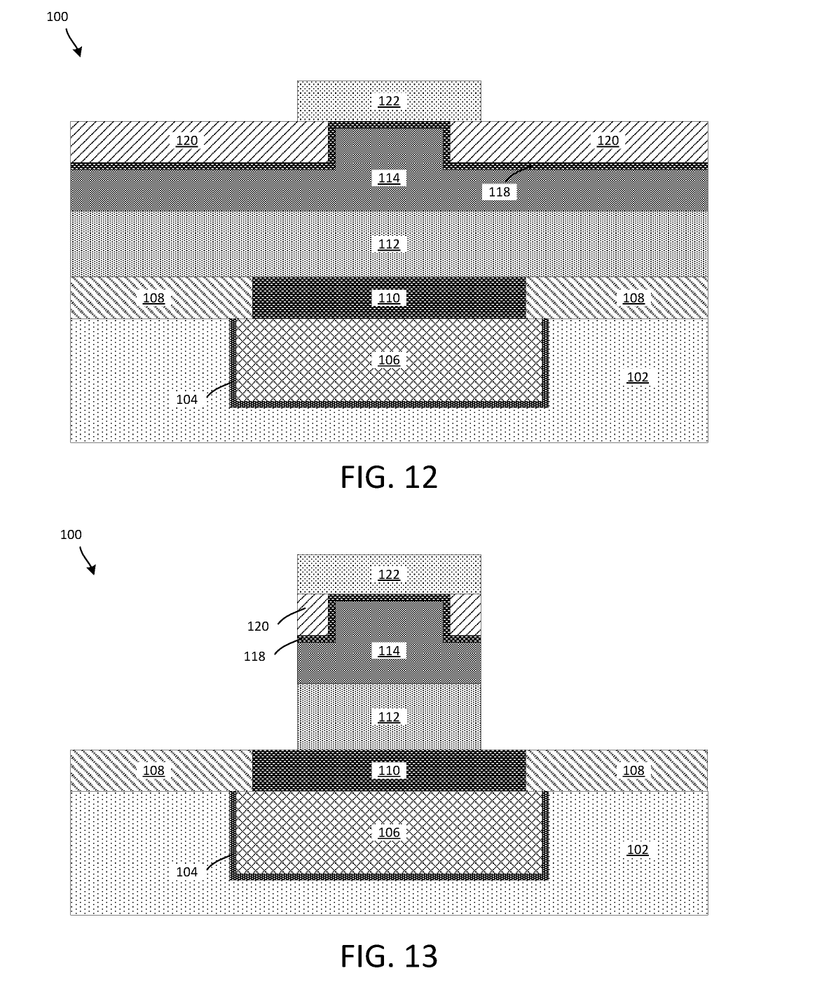

Referring now to FIG. 12, this figure is a cross-sectional view of the semiconductor device 100 of FIG. 11 after additional fabrication operations, according to embodiments. As shown in FIG. 12, a second hardmask layer 122 is formed on the encapsulation layer 120 and the tunnel barrier layer 118 to allow for the subsequent patterning of the MTJ pillar. In certain examples, the material of the second hardmask layer 122 may be TaN or any other suitable material(s). For example, the second hardmask layer 122 may include one or more of the following materials: TaN; WCN; TiN; TaAlN; WN; TEOS; low-κ and ULK etc.

Referring now to FIG. 13, this figure is a cross-sectional view of the semiconductor device 100 of FIG. 12 after additional fabrication operations, according to embodiments. As shown in FIG. 13, the pattern of the second hardmask layer 122 is transferred to form the reference layer 114 and the tunnel barrier layer 118 of the magnetic tunnel junction (MTJ) stack (or MTJ pillars). In particular, the second hardmask layer 122 is used to etch through the encapsulation layer 120, the tunnel barrier layer 118, the reference layer 114, and the bottom electrode 112. In one example, a two-step material removal process is used to form the MTJ pillars. During these etching steps, due to the presence of the encapsulation layer 120 in the areas around the mesa structure 119 of the reference layer 114, even if there is a certain amount of metal re-sputtering from the bottom electrode 112 the material of the encapsulation layer 120 helps to minimize or prevent any electrical shorting between the reference layer 114 and the magnetic free layer 126 (see, FIG. 19).

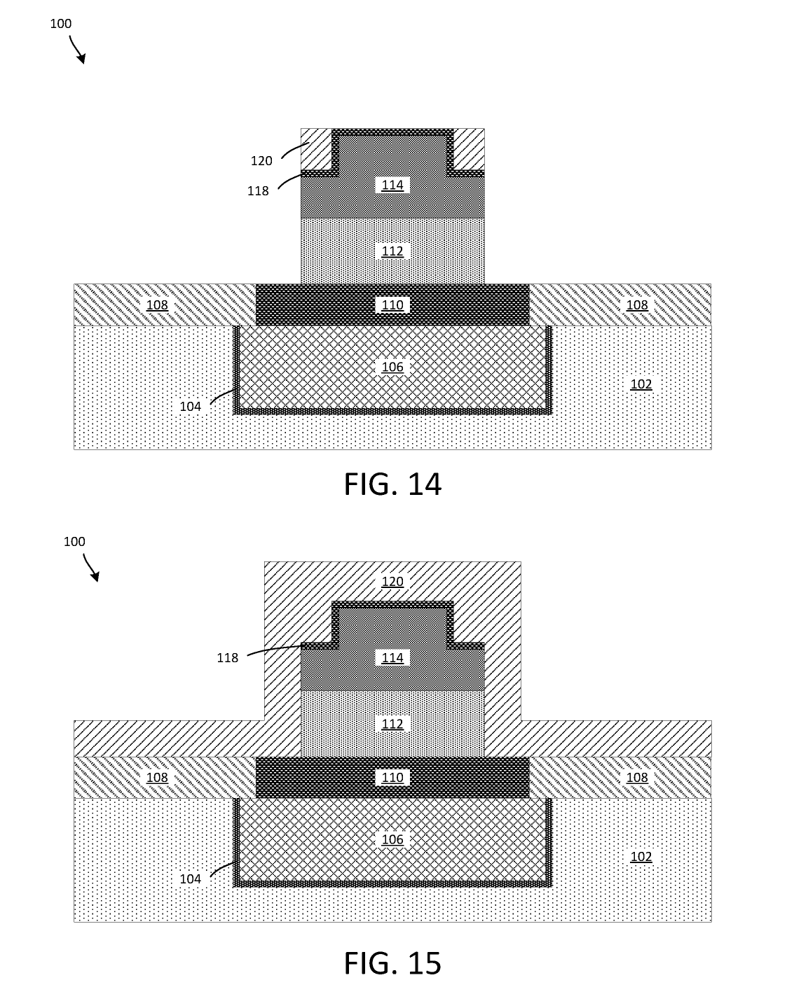

Referring now to FIG. 14, this figure is a cross-sectional view of the semiconductor device 100 of FIG. 13 after additional fabrication operations, according to embodiments. As shown in FIG. 14, a suitable material removal process is used to remove the second hardmask layer 122.

Referring now to FIG. 15, this figure is a cross-sectional view of the semiconductor device 100 of FIG. 14 after additional fabrication operations, according to embodiments. As shown in FIG. 15, additional material of the encapsulation layer 120 is deposited over the entire MTJ pillar structure.

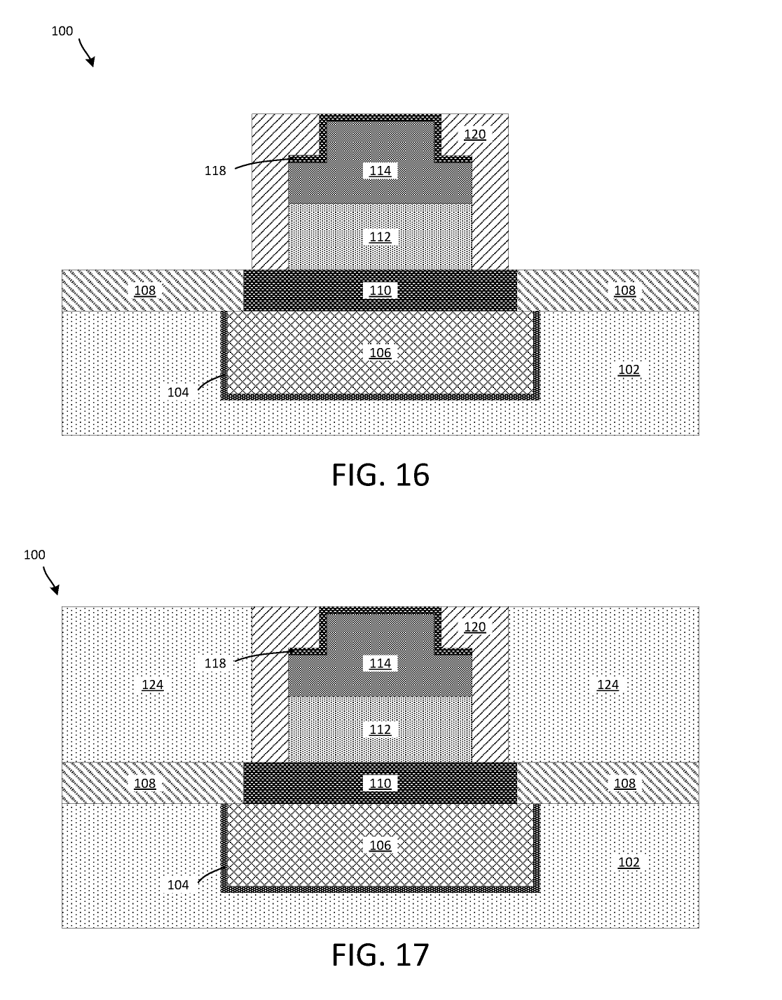

Then, as shown in FIG. 16, a suitable material removal process is used to etch back the additional material of the encapsulation layer 120 to again expose the dielectric cap 108 and the tunnel barrier layer 118.

Referring now to FIG. 17, this figure is a cross-sectional view of the semiconductor device 100 of FIG. 16 after additional fabrication operations, according to embodiments. As shown in FIG. 17, a second ILD layer 124 is formed on the dielectric cap 108 and around the encapsulation layer 120. In certain examples, an optional material removal process (e.g., CMP) may be used to planarize and remove any excess material of the second ILD layer 124. The material of the second ILD may be the same material or include different materials than that of the first ILD layer 102.

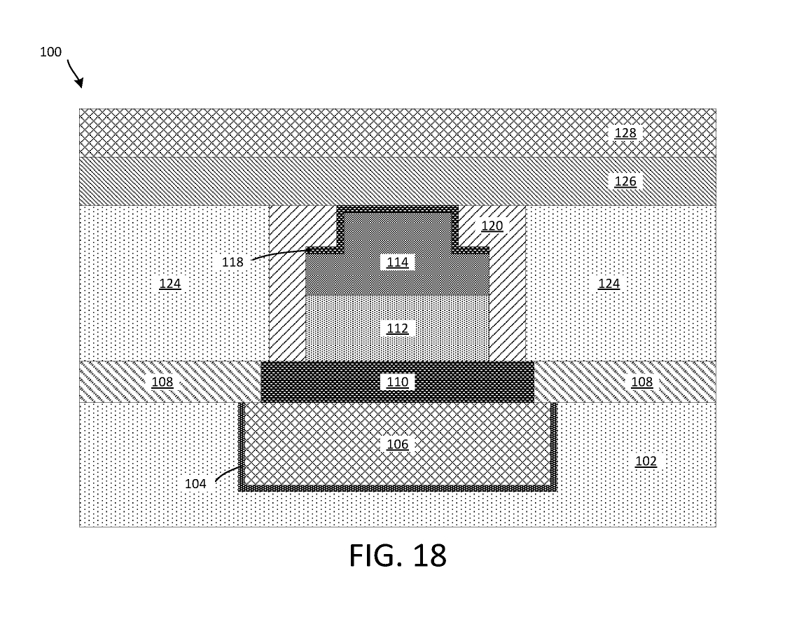

Referring now to FIG. 18, this figure is a cross-sectional view of the semiconductor device 100 of FIG. 17 after additional fabrication operations, according to embodiments. As shown in FIG. 18, a magnetic free layer 126 is formed on the tunnel barrier layer 118, the encapsulation layer 120 and the second ILD layer 124. In general, the magnetic free layer 126 may have a magnetic moment or magnetization state that can be flipped. Then, a top electrode 128 is formed on the magnetic free layer 126. In certain examples, the top electrode 128 may comprise Cu, Nb, NbN, W, WN, Ta, TaN, Ti, Ru, Mo, Cr, V, Pd, Pt, Rh, Sc, Al and other high melting point metals or conductive metal nitrides, or any other suitable conductive material(s) for use in an electrode.

Referring now to FIG. 19, this figure is a cross-sectional view of the semiconductor device 100 of FIG. 18 after additional fabrication operations, according to embodiments. As shown in FIG. 19, a suitable material removal process is used to pattern the magnetic free layer 126 and the top electrode 128. In certain examples, the widths of these layers may the same or similar as the widths of the reference layer 114 and the bottom electrode 112. In certain examples, the width of the mesa structure 119 of the reference layer has a width that is less than the widths of the bottom electrode 112, the tunnel barrier layer 118, the magnetic free layer 126 and the top electrode 128, which enables the filling of the encapsulation layer 120 material in the areas around the mesa structure 119. As mentioned above, due to the presence of the encapsulation layer 120 in the areas around the mesa structure 119 of the reference layer 114, even if there is a certain amount of metal re-sputtering from the bottom electrode 112 the material of the encapsulation layer 120 helps to minimize or prevent any electrical shorting between the reference layer 114 and the magnetic free layer 126.

In certain embodiments, each layer of the MTJ stack (or MTJ pillar) may have a thickness less than an angstrom to a thickness of several angstroms or nanometers. Examples of typical materials in an MTJ stack can include MgO, MgAlOₓ, AlOₓ, etc. for the tunnel barrier layer 118, CoFeB for the magnetic free layer 126, and a plurality of layers comprised of different materials for the reference layer 114. It should be appreciated that the MRAM stack is not limited to these materials, or the layers described above. That is, the MRAM stack can be composed of any known stack of materials used in MRAM devices. In certain embodiments, the MTJ stack can have a combination of ferro and anti-ferromagnetic metals such as Co/Fe/Ni, other metals such as Pt/Ir as well as B. Moreover, it should be appreciated that the MTJ stack may include additional layers, omit certain layers, and each of the layers may include any number of sublayers. It should be appreciated that this MRAM stack structure shown in FIG. 19 is only an example, and any other suitable MRAM stack structure known to one of skill in the art may be utilized.

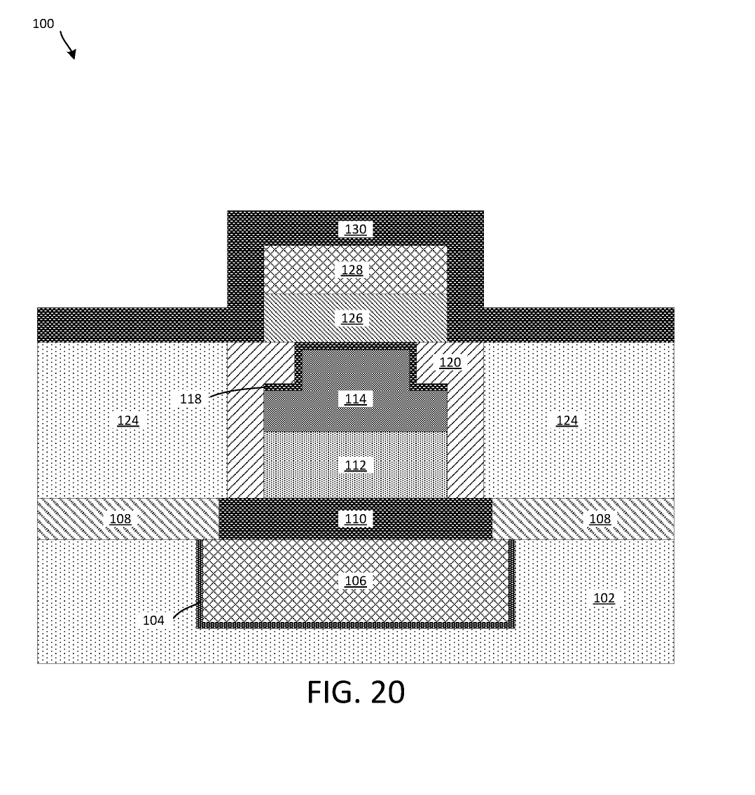

Referring now to FIG. 20, this figure is a cross-sectional view of the semiconductor device 100 of FIG. 19 after additional fabrication operations, according to embodiments. As shown in FIG. 20, a second encapsulation layer 130 is deposited over the entire MTJ pillar structure.

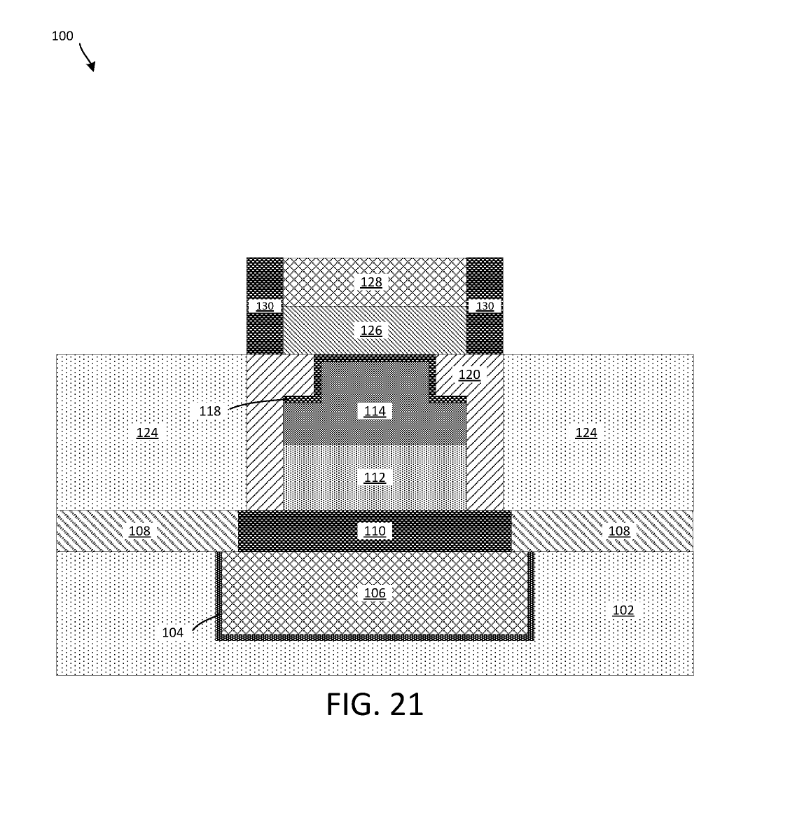

Then, as shown in FIG. 21, a suitable material removal process is used to etch back all horizontal portions of the second encapsulation layer 130 to expose the top electrode 128. In certain examples, the second encapsulation layer 130 may comprise the same or different materials as the encapsulation layer 120. As also shown in FIG. 21, vertical portions of the second encapsulation layer 130 remain to cover the sidewalls of the magnetic free layer 126 and the top electrode 128.

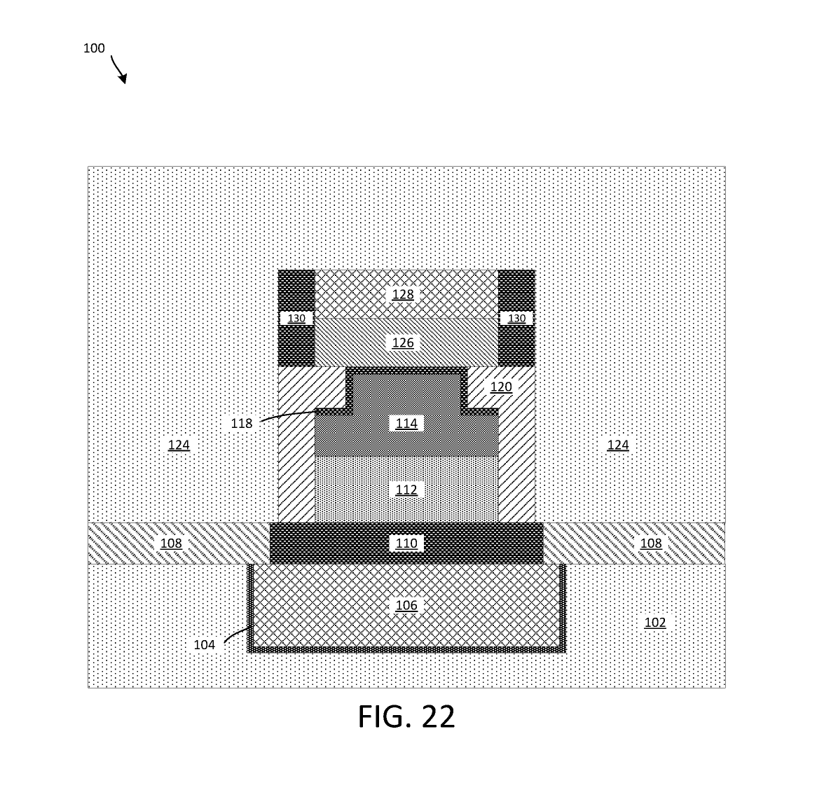

Referring now to FIG. 22, this figure is a cross-sectional view of the semiconductor device 100 of FIG. 21 after additional fabrication operations, according to embodiments. As shown in FIG. 22, additional material of the second ILD layer 124 (or dielectric encapsulation layer) is deposited over the entire surface of the semiconductor device 100 to cover the dielectric cap 108 and the MTJ stack structure. The additional material of the second ILD layer 124 is deposited onto the semiconductor device 100 to increase the overall thickness of this layer and to fill in the spaces between adjacent MTJ stacks. It should be noted that because the second ILD layer 124 is formed in separate steps (see, FIGS. 17 and 22), the thickness of the material added to the second ILD layer 124 has a low aspect ratio (i.e., the thickness of the material added is low compared to the width of the material added). This low aspect ratio for the material deposition is beneficial because it reduces or eliminates the possibility of creating ILD voids. As mentioned above, a potential problem with forming thick high aspect ratio ILD layer (e.g., in one step) is that ILD voids can be created which can lead to potential issues with electrical shorting between the electrodes of adjacent MRAM stacks.

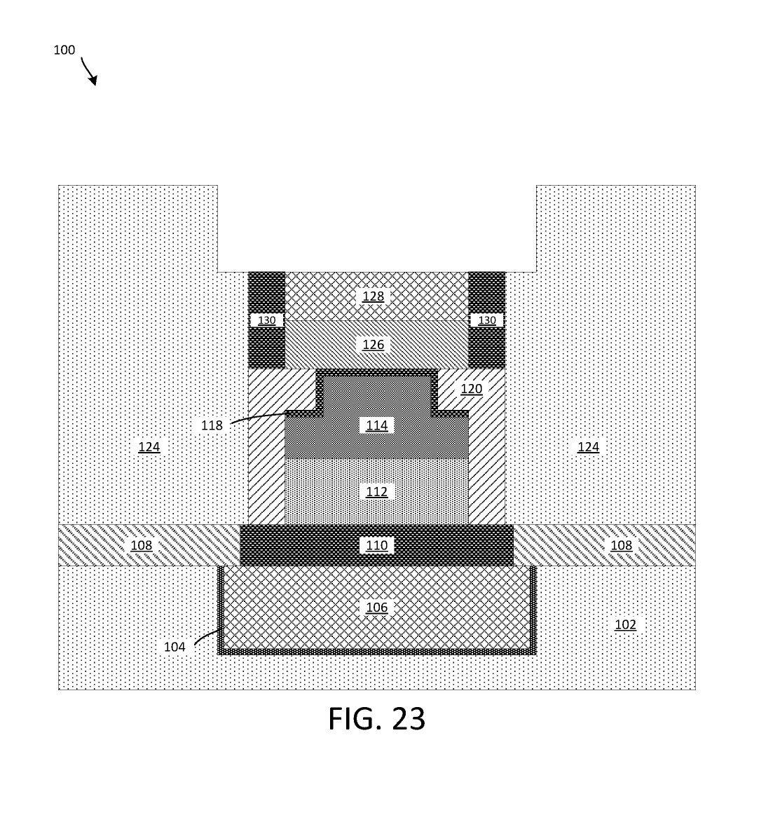

Then, as shown in FIG. 23, suitable patterning and material removal processes are once again performed on the second ILD layer 124 to expose a portion of the top surface of the top electrode 128. In certain examples, the size of the openings formed in the second ILD layer 124 may be the same as the size of the openings that were formed in the first ILD layer 102 as shown in FIG. 1.

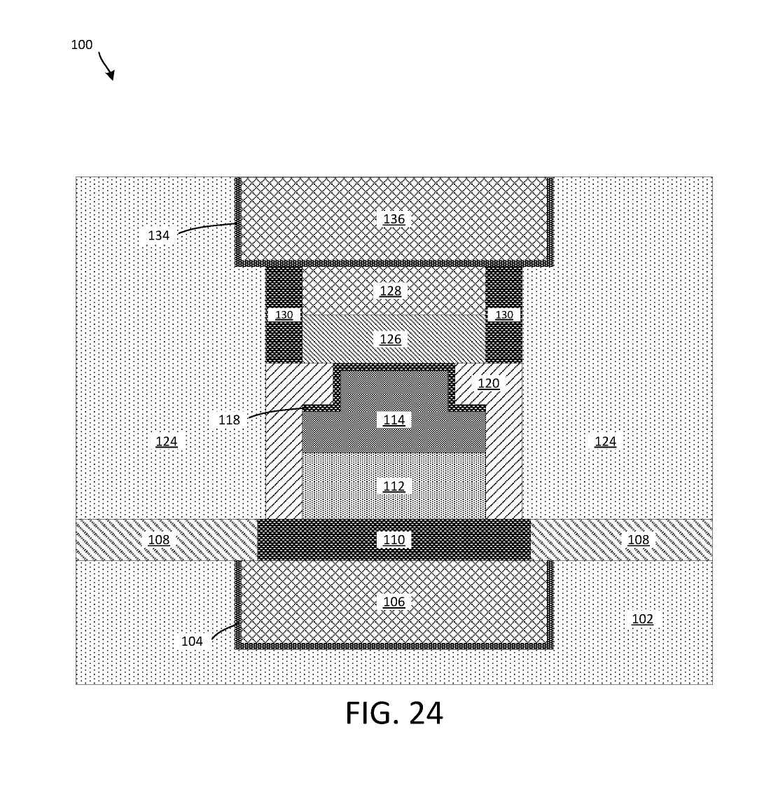

Referring now to FIG. 24, this figure is a cross-sectional view of the semiconductor device 100 of FIG. 23 after additional fabrication operations, according to embodiments. As shown in FIG. 24, after the formation of the opening in the second ILD layer 124, a top barrier layer 134 is first formed in the top metal contact holes. The top barrier layer 134 may comprise, for example, Ta or TaN. Then, a top metal contact 136 (or top metal layer) is deposited on the top barrier layer 134 and fills in the remainder of the top metal contact hole. This top metal contact 136 may be included in one of the BEOL layers. In certain examples, the top metal contact 136 (e.g., an M2 level interconnect wire) may include, Cu, Co, Nb, NbN, W, WN, Ta, TaN, Ti, TiN, Ru, Mo, Cr, V, Pd, Pt, Rh, Sc, Al and other metals or conductive metal nitrides. It should be appreciated that the interconnect structure shown in FIG. 24 is merely one example, and any other suitable interconnect structure (e.g., number of layers, size, number of contacts, etc.) may be used. Then, in certain examples, an optional material removal process such as chemical mechanical planarization (CMP) may be performed to planarize the surface of the semiconductor device 100.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art.

What is claimed is:

1. A semiconductor device comprising:
a magnetic tunnel junction (MTJ) stack including:
a reference layer including an inner portion and an outer portion surrounding the inner portion, where the inner portion has a greater thickness than the outer portion,
a tunnel barrier layer, and
a magnetic free layer.

2. The semiconductor device according to claim 1, wherein the tunnel barrier layer is formed on top surfaces of both the inner portion and the outer portion of the reference layer.

3. The semiconductor device according to claim 2, wherein the tunnel barrier layer is also formed on vertical sidewalls of the inner portion of the reference layer.

4. The semiconductor device according to claim 1, wherein the inner portion and the outer portion of the reference layer both have a cylindrical shape.

5. The semiconductor device according to claim 1, further comprising a encapsulation layer formed between the outer portion of the reference layer and the magnetic free layer.

6. The semiconductor device according to claim 5, wherein the encapsulation layer comprises a dielectric material.

7. The semiconductor device according to claim 1, further comprising:
a bottom electrode formed adjacent to the reference layer;
a top electrode formed adjacent to the magnetic free layer; and
a dielectric fill layer formed around the MTJ stack, the top electrode, and the bottom electrode.

8. The semiconductor device according to claim 7, further comprising a bottom metal contact electrically connected to the bottom electrode, and a top metal contact electrically connected to the top electrode.

9. The semiconductor device according to claim 8, further comprising a metal cap layer between the bottom metal contact and the bottom electrode.

10. A semiconductor device comprising:
a magnetic tunnel junction (MTJ) stack including:
a reference layer having a mesa structure that includes a lower portion having a first width and an upper portion having a second width, where the first width is greater than the second width,
a tunnel barrier layer, and
a magnetic free layer.

11. The semiconductor device according to claim 10, wherein the tunnel barrier layer is formed on top surface of both the lower portion and the upper portion of the reference layer.

12. The semiconductor device according to claim 11, wherein the tunnel barrier layer is also formed on vertical sidewalls of the upper portion of the reference layer.

13. The semiconductor device according to claim 10, wherein the lower portion and the upper portion of the reference layer both have a cylindrical shape.

14. The semiconductor device according to 10, further comprising a encapsulation layer formed between the lower portion of the reference layer and the magnetic free layer.

15. The semiconductor device according to claim 14, wherein the encapsulation layer comprises a dielectric material.

16. The semiconductor device according to claim 10, wherein the magnetic free layer has a larger width than the width of the upper portion of the reference layer.

17. An electronic device comprising:
a semiconductor device including a magnetic tunnel junction (MTJ) stack, the MTJ stack including:
a reference layer including an inner portion and an outer portion surrounding the inner portion, where the inner portion has a greater thickness than the outer portion,
a tunnel barrier layer, and
a magnetic free layer.

18. The electronic device according to claim 17, wherein the tunnel barrier layer is formed on top surfaces of both the inner portion and the outer portion of the reference layer.

19. The electronic device according to claim 18, wherein the tunnel barrier layer is also formed on vertical sidewalls of the inner portion of the reference layer.

20. The electronic device according to claim 17, wherein the inner portion and the outer portion of the reference layer both have a cylindrical shape.
